(19) United States
(12) Patent Application Publication
(10) Pub. No.: US 2005/0150453 A1
(43) Pub. Date: Jul. 14, 2005

(54) Bladder-based apparatus and method for dispensing coatings

(76) Inventors: Walter Neal Simmons, Durham, NC (US); Walter John Simmons, Martinsburg, WV (US)

Correspondence Address: COLLIER SHANNON SCOTT, PLLC, 3050 K STREET, NW, SUITE 400, WASHINGTON, DC, 20007, US

(21) Appl. No.: 10/920,211

(22) Filed: Aug. 18, 2004

Related U.S. Application Data
(63) Continuation of application No. PCT/US03/05275, filed on Feb. 21, 2003.
(60) Provisional application No. 60/358,393, filed on Feb. 22, 2002.

(51) Int. Cl. C23C 16/00

(52) U.S. Cl. 118/715; 427/248.1

(57) ABSTRACT

The invention is related to a coating delivery system that includes at least one pressure vessel having an inner surface, a flexible bladder disposed in a first pressure vessel and having an open condition and a closed condition, an internal region disposed between the inner surface and the bladder, and a deliverable substance including a coating component interspersed with at least one of liquefied carbon dioxide and supercritical carbon dioxide. The deliverable substance is disposed in one of the flexible bladder and the internal region, and the pressure-conveying fluid is received in the other to exert pressure on the deliverable substance and thereby permit transport thereof when the flexible bladder is in the open condition.

### CROSS-REFERENCE TO RELATED APPLICATIONS

This application is a continuation of the U.S. National Stage designation of co-pending International Patent Application PCT/US03/05275 filed Feb. 21, 2003, which claims the benefit of U.S. Provisional Application No. 60/358,393 filed Feb. 22, 2002, the entire contents of which are expressly incorporated herein by reference thereto.

### FIELD OF THE INVENTION

The invention is related to an apparatus and method for dispensing coatings. In particular, the invention is related to a delivery system that includes at least one pressure vessel within which is stored a deliverable substance having a coating component interspersed with a fluid component.

### BACKGROUND OF THE INVENTION

The use of volatile organic compounds as carriers for the delivery of coatings is well-known. However, increasingly there is a need for environmentally friendly carriers which minimize the use of organic carriers such as organic solvents. Supercritical fluids have emerged as such a viable carrier in coating applications, particularly in applications requiring the delivery of a substance in spray form. While supercritical fluids are known to have solvating powers similar to organic solvents, they also present advantages over organic solvents because of their higher diffusivities, lower viscosities, and lower surface tensions.

A supercritical carrier may be considered any compound at a temperature and pressure above certain critical values of temperature and pressure. The critical temperature of a compound is the temperature above which the pure compound in gaseous state cannot be converted to a liquid, while a compound's critical pressure is the vapor pressure of the pure compound in gaseous state at the critical temperature. The critical point of the compound occurs at the temperature and pressure at which the gas and liquid phases are no longer separately defined, but instead a fluid exists in a state that is considered neither liquid nor gas. In the supercritical state, a fluid confers the carrier properties expected from a liquid while at the same time providing transport characteristics expected from gases.

Various compounds are known to exist as supercritical fluids, including ethylene, carbon dioxide, ethane, nitrous oxide, propane, and even methanol and water. The low cost and ready availability of supercritical carbon dioxide have made it a popular choice for a variety of applications. Also, with its critical temperature of 31.1° C., critical pressure of about 73 atm, and critical density of about 470 kg/m³, supercritical carbon dioxide has properties amenable to applications using standard pressure vessel technology.

Various applications have been explored for supercritical carriers, including use in the delivery of protective coatings to various commercial building substrates such as marble, stone, cast stone, architectural terra cotta, concrete, and concrete block. The degradation of such materials due to pollution, acid rain, and other destructive forces can be substantially decreased if a relatively thin protective coating is applied.

Several supercritical fluid technologies have been disclosed by investigators. For example, U.S. Pat. No. 4,923,720 to Lee et al. is directed to the use of supercritical fluids as diluents in the liquid spray application of coatings. A process and apparatus for coating substrates is provided in which a supercritical fluid, such as supercritical carbon dioxide fluid, is used as a viscosity reduction diluent for coating formulations.

However, prior art methods and devices for applying coatings using supercritical fluids suffer from complexity and concomitant bulky equipment, rendering the technology inconvenient to use and inaccessible to many potential customers. Commercial and laboratory equipment for applying coatings using supercritical fluids generally fall into two classes, batch and continuous. Typically, the main storage element of prior art batch systems is a floating piston accumulator. The coating material and supercritical fluid are held captive on one side of the piston, while the pressurization fluid is stored on the other. In such systems, the coating material and CO₂ are added at a pressure typically above 1000 psi so that the CO₂ remains in a liquid state. Such an arrangement requires high-pressure pumps. After the desired amounts of coating material and CO₂ have been added, the two components must be mixed. Mixing usually is effected by circulating material in and out of the piston accumulator. The pressurizing fluid, disposed on the other side of the piston accumulator, is used to effect transport of the deliverable substance through a hose to a spray nozzle. Such batch systems are heavy due to the weight of the piston accumulator, high-pressure pumps, and associated controls. The weight of commercial units ranges between about 3000 lbs and about 1500 lbs. for equipment capable of delivering 6 kgs per batch, not including the CO₂ supply bottle.

Continuous systems typically require two or three high-pressure pumps, along with complex flow meters and controls for accurately metering and mixing the coating material and supercritical fluid components. Multiple control loops and a programmable logic controller may be required. Such systems are less common, due to the required level of sophistication of controls. Further, although the commercial, continuous systems are capable of supplying about 100 grams to about 300 grams per minute of deliverable product, they are heavy, typically weighing between about 180 lbs. and 1000 lbs.

The above-described batch and continuous systems are heavy, bulky, require multiple high-pressure pumps, and require heavy CO₂ cylinders with high stored energies. These systems also require significant equipment maintenance, as well as an additional energy source to power pumps and controls.

Thus, there exists a need for an improved apparatus and an improved method for dispensing coatings using supercritical fluids. There also exists a need for an apparatus with simplicity in design, compactness, and portability so that the device may be manually transported. Moreover, there exists a need for methods and devices that can deliver coatings with controllable composition and thickness.

### SUMMARY OF THE INVENTION

The invention is related to a coating delivery system including a first pressure vessel having an inner surface, a flexible bladder disposed in the first pressure vessel and having an open condition and a closed condition, and an internal region disposed between the inner surface and the bladder. The coating delivery system also includes a deliverable substance having a coating component interspersed with at least one of liquefied carbon dioxide and supercritical carbon dioxide. A pressure-conveying fluid is provided (1) at a pressure greater than the vapor pressure of carbon dioxide if the deliverable substance comprises liquefied carbon dioxide, or (2) at a pressure greater than the critical pressure of carbon dioxide if the deliverable substance is supercritical carbon dioxide. The deliverable substance is disposed in one of the flexible bladder and the internal region, and the pressure-conveying fluid is received in the other to exert pressure on the deliverable substance and thereby permit transport thereof when the flexible bladder is in the open condition. The flexible bladder may be formed of an elastomeric material, while the first pressure vessel may be formed of carbon fiber.

The coating delivery system may further include a second pressure vessel, with the pressure-conveying fluid being stored in the second pressure vessel in communication with one of the internal region of the first pressure vessel and the flexible bladder. A regulator may be provided for regulating the transport of pressure-conveying fluid from the second pressure vessel to the first pressure vessel. In some embodiments, the pressure-conveying fluid may be a gas, while in other embodiments the pressure-conveying fluid may be a liquid. Also, the coating component may be an enamel, an alkylsilicone resin, or a fluorinated resin.

The invention also is related to a method of applying a coating to a substrate including: separating a deliverable substance from a pressurizing fluid with a flexible membrane disposed in a first pressure vessel, the deliverable substance comprising a coating component interspersed with at least one of liquefied carbon dioxide and supercritical carbon dioxide; allowing the pressurizing fluid to apply pressure to the deliverable substance (1) at a pressure at least the vapor pressure of carbon dioxide if the deliverable substance comprises liquefied carbon dioxide, or (2) at a pressure at least the critical pressure of carbon dioxide if the deliverable substance comprises supercritical carbon dioxide; delivering the deliverable substance to the substrate.

In some embodiments, the pressurizing fluid may be provided in a second pressure vessel that communicates with the first pressure vessel. The deliverable substance may be provided in a bladder in the first pressure vessel, or the pressurizing fluid may be provided in a bladder in the first pressure vessel. The method may additionally include heating the deliverable substance prior to spray discharge, pumping the deliverable substance, agitating the deliverable substance, and/or recirculating a portion of the deliverable substance.

### BRIEF DESCRIPTION OF THE DRAWINGS

Preferred features of the present invention are disclosed in the accompanying drawings, wherein similar reference characters denote similar elements throughout the several views, and wherein:

FIG. 1 shows a partial cross-sectional view of an embodiment of a delivery system according to the present invention with a single outer pressure vessel and an inner bladder; and

FIG. 2 shows a partial cross-sectional view of another embodiment of a delivery system according to the present invention with two pressure vessels, one of which includes an inner bladder.

### DETAILED DESCRIPTION OF THE PREFERRED EMBODIMENT

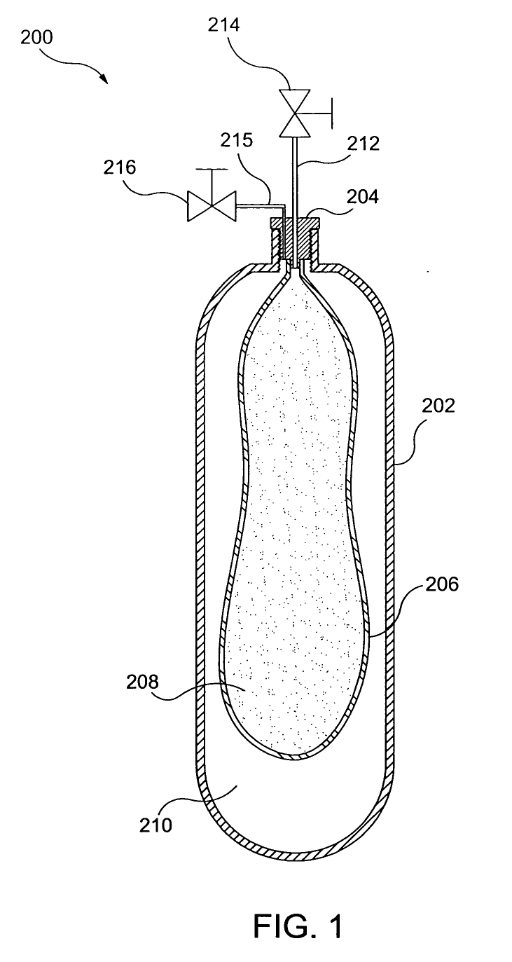

Referring to FIG. 1, there is shown an exemplary delivery system according to a first embodiment of the present invention. Delivery system 200 includes a pressure vessel 202 with a cylinder fitting 204 and a flexible bladder 206. A quantity of a deliverable substance 208 is preferably stored in bladder 206, while a pressurizing gas is stored in region 210 between vessel 202 and bladder 206. Deliverable substance 208 preferably includes a desired coating component interspersed with a fluid component. The coating component preferably is chosen to suit a desired application, and in the preferred embodiment is a paint or resin suitable for application to commercial building substrates. Among the coating components contemplated are acrylics, alkylsilicone resins, and fluorinated resins, however the present invention also may apply to other organics, inorganics, hydrocarbons, and silicones. Exemplar coating components include such substances as Sherwin Williams Industrial Enamel HS #B54TZ404, a high performance all-purpose solvent reducible water repellent for mineral substrates such as product designation BS 290 (an alkylsilicone resin with alkoxy groups) supplied by Wacker Silicones Corporation (Adrian, MI), and a formulated composition whose main ingredient is a fluorinated resin with molecular weight less than 15,000. In general, both monomers and polymers may be used. The fluid component preferably is chosen from compounds suitable for use as supercritical solvents, including CO₂, C₂H₄, N₂O, NH₃, n-Cs, n-C₄, CCl₂F₂, and CHF₃, and most preferably is CO₂. A delivery line 212 communicates with, and is sealed to, an opening in bladder 206, and terminates at an isolation valve 214. Preferably, isolation valve 214 is connected to a regulator (not shown), through which deliverable substance 208 flows.

A fluid delivery line 215 communicates with region 210 in vessel 202, so that region 210 may be filled with fluid, preferably a pressurizing gas. A fluid delivery valve 216 may be connected to a source of fluid for filling region 210. Any of a wide range of pressurization gases may be used, for example air or nitrogen which are relatively inexpensive. In an alternate embodiment, region 210 is filled with a liquid. High pressure rated rigid cylinders are preferably used, permitting safe storage of fluids such as liquid carbon dioxide at ambient temperatures. Such cylinders should preferably be rated for use over a pressure range of about 200 psi to about 4500 psi. To prevent cylinder rupture due to over-pressurization, a frangible disk, relief valve, or other safety mechanism may be employed.

Gas cylinders with a head space (i.e., without an internal bladder) contain both liquid and gas when full. For example, at 70° F., a full carbon dioxide gas cylinder has carbon dioxide in both liquid and gaseous states. The liquid carbon dioxide may fill about two-thirds of the space in the cylinder, while the remainder of the cylinder has carbon dioxide gas. It is known that some exchange occurs between the liquid and gas. This is also true for cylinders that are provided with several types of gases having different densities. Helium-headspace (HHS) carbon dioxide, otherwise known as helium head pressure (HHP) carbon dioxide, may be used, with carbon dioxide in the deliverable substance and helium present in the head space. In such a case, some exchange can be expected between the headspace filler gas and the carbon dioxide. In particular, some researchers have shown that some of the helium may dissolve in the liquid carbon dioxide. Because of the exchange, HHS carbon dioxide contains helium as an impurity in the liquid carbon dioxide. The presence of the impurity can have a measurable impact in some sensitive applications such as supercritical fluid extraction and supercritical fluid chromatography.

The prior art suggests that carbon dioxide would be expected to be found in the head space. From such indication, it would be expected that the composition of the deliverable substance would vary as the deliverable substance is emptied from the pressure vessel, due to the transport of some carbon dioxide from the deliverable substance to the head space. Further, in an experiment using a non-bladder delivery system and an exemplar formulated composition and CO₂ deliverable substance, a 4.5% by weight change in composition was found between 20° C. and 40° C. For the test, the coating component was a formulated composition whose main ingredient is a fluorinated resin, as described previously. Advantageously, the bladder-based embodiments of the present invention permit a constant composition of the deliverable substance to be delivered, for example by spray, independent of temperature and pressure.

In the preferred embodiment, flexible bladder 206 is generally impermeable to deliverable substance 208 and to the pressurizing gas in region 210, thereby providing a physical barrier. Thus, the construction of delivery system 200 advantageously permits deliverable substance 208 to be delivered in a “pure” state, i.e. without the presence of dissolved pressurizing gas as may occur with other systems disclosed herein. As a result, a consistent composition of deliverable substance 208 may be dispensed. In addition, higher pressures may be applied (indirectly) to deliverable substance 208 during dispensing, because there is no concern about reaching the saturation pressure of the pressurizing gas with respect to deliverable substance 208.

In some embodiments, flexible bladder 206 is formed of a metalisized polymer. Preferably, bladder 206 is formed of an elastomeric material. Bladder 206 is sized as desired to fit within pressure vessel 202, and may initially fill the inner space of vessel 202 so that a region 210 is not initially present. As pressurizing gas is delivered to vessel 202 to fill a region 210, pressure is applied to bladder 206. Consequently, bladder 206 collapses to a smaller volume, and accordingly deliverable substance 208 is expelled in an amount about the same as the decrease in volume. Among the additional advantages realized with delivery system 200 include the potential complete expulsion of the stored deliverable substance 208 from bladder 206 when it has completely collapsed, so that waste is eliminated. Also, while dense gas and/or liquid might remain at the bottom of a pressure vessel when a dip tube is used, such excess is avoided. In addition, delivery system 200 may be used in any orientation, using standard commercially available cylinders. Finally, because of the design of delivery system 200, deliverable substance 208 may be a supercritical fluid. Preferably, when deliverable substance 208 includes a supercritical fluid, the pressure in region 210 is above the critical pressure of the supercritical fluid.

Delivery system 200 may be supplied “turnkey,” so that a user need only unpack the system and attach a suitable spray hose with an orifice to valve 214. The system may be provided with suitable pressurizing gas in region 210, and a bladder 206 filled with a deliverable substance 208. Such a system may initially have a high pressure gas, i.e., 4000 psi in region 210. As deliverable substance is expelled from bladder 206, the pressure in region 210 decreases, along with the corresponding expulsion pressure of deliverable substance 208.

In an alternate embodiment, deliverable substance 208 may instead be stored in region 210, while a pressurizing gas is stored in bladder 206. Bladder 206 is thus filled, like a balloon, so that pressure is exerted against deliverable substance 208 to expel it from pressure vessel 202. Geometrically, however, a bladder of a shape that would conform to the inner walls of vessel 202 may be more difficult to produce. Furthermore, regardless of whether pressurizing gas is stored in region 210 or bladder 206, the pressurizing gas storage location serves as an accumulator, compensating for volume changes occurring, for example, due to changes in temperature.

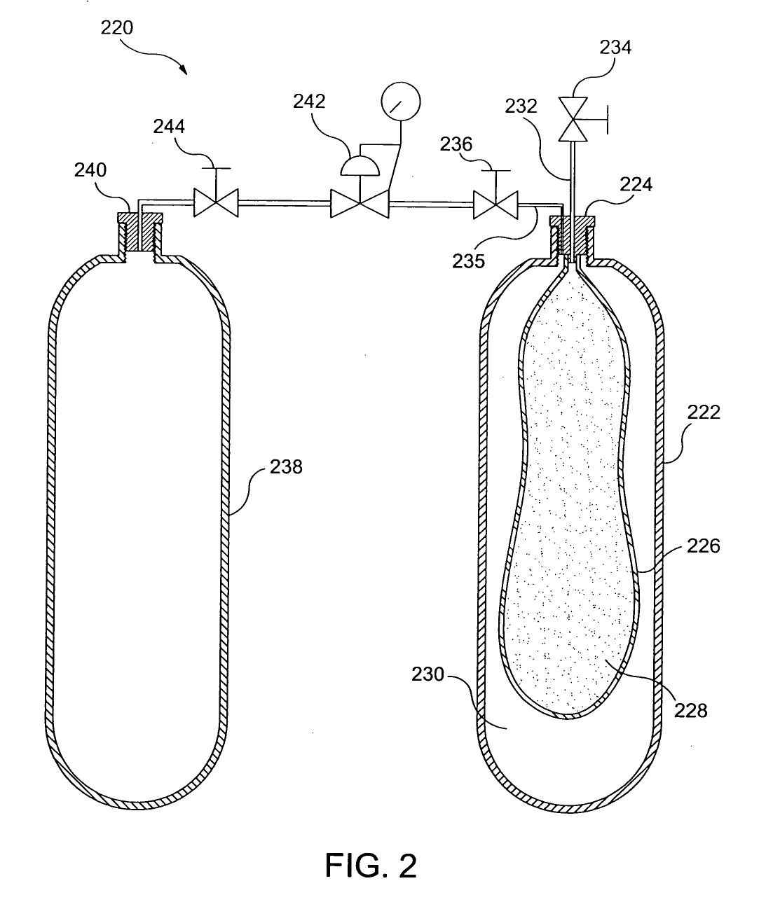

Turning to FIG. 2, an exemplary preferred embodiment of a delivery system according to the present invention is shown. Delivery system 220 includes a pressure vessel 222 with a cylinder fitting 224 and a flexible bladder 226. A quantity of a deliverable substance 228 is preferably stored in bladder 226, while a pressurizing gas is stored in region 230 between vessel 222 and bladder 226. A delivery line 232 communicates with, and is sealed to, an opening in bladder 226, and terminates at an isolation valve 234. A fluid delivery line 235 communicates with region 230 in vessel 222, so that region 230 may be filled with fluid, preferably a pressurizing gas. A fluid delivery valve 236 is connected to a source of fluid for filling region 230. In the preferred embodiment, a pressure vessel 238 with a cylinder fitting 240 is provided. Cylinders 222 and 238 communicate through fluid delivery line 235. In particular, fluid delivery valve 236, regulator 242, and pressurizing cylinder valve 244 are connected between cylinders 222 and 238. Bladder 226 stores a quantity of a deliverable substance 228, as described above, while constant pressure is maintained in region 230 by regulator 242. In one non-limiting exemplary arrangement, cylinder 238 may be filled to an initial pressure of 3000 psi with nitrogen gas, while region 230 of cylinder 222 may be pressurized with the nitrogen gas at a generally constant pressure of 1500 psi using regulator 242.

Advantageously, use of delivery system 220 with two pressure vessels 222 and 238 permits a constant spray pressure to be achieved for deliverable substance exiting isolation valve 234. Furthermore, when a user stops spraying deliverable substance 228 and some remains in the delivery hose, the remaining deliverable substance is permitted to return to its initial source (i.e., bladder 226 which re-expands to accommodate the fluid and coating component), thereby avoiding excessive pressure increase in the delivery hose.

In preferred embodiments of the present invention, a heated hose is connected to the delivery system. The heated hose, for example, permits a desired coating component intermixed with liquid/supercritical carbon dioxide, to be delivered with desired spray characteristics such as droplet size. In addition, heating may permit the deliverable substance to be discharged without solidification proximate the nozzle, and thus plugging of the delivery system can be averted. In one preferred embodiment, a substance enters the final delivery hose at a temperature of 20° C. and is heated to a temperature of 50° C. at the exit of the hose proximate the nozzle.

Preferably, pressure vessels 202, 222, 238 are provided as cylinders or other suitably rigid tanks. Although carbon fiber cylinders are preferred, other cylinders such as fiberglass, aramid, aluminum or steel cylinders may be used.

In addition, pressure vessels and or bladders disclosed in the present invention may be provided with means for producing agitation, such as magnetic stirrers, one or more mixing balls, or other agitation arrangements. Such agitation is advantageous because when pressurizing gas is applied to the head space (or exterior of a bladder), it causes some of the gaseous CO₂ to be liquefied due to the increase in pressure. The CO₂ is less dense than the coating component, and thus stratifies above the coating component/CO₂ mixture creating a non-homogenous mixture. Further, homogenous systems also may develop density gradients, over time, due to the vastly different densities of the mixture components (coating component and CO₂). Preferably, mixing is undertaken after pressurization.

In one exemplary, preferred embodiment of the present invention, the delivery system is provided in compact, lightweight form to permit transport in a midsize automobile and single-person handling. Such an embodiment may, for example, have two pressure vessels, an overall size of 26″×12″×48″, and an overall weight of about 70 lbs. Cylinders are preferably pre-filled, requiring minimal preparation by users, and the delivery system may be used in a batch process. In addition, due to the size and weight, and concomitantly the nature of the materials that are used, the delivery systems may be shipped by common carrier.

Advantageously, the embodiments of the present invention may be operated without the used of external energy sources, which for example, are typically required with prior art delivery systems which employ one or more pumps and control systems. Pumps, in particular, require significant energy. Moreover, the embodiments of the present invention preferably only require an energy source for the heated discharge hose. Such an energy source may be provided in a small battery pack, which may be directly attached to the delivery system or connected to the heated discharge hose yet carried, for example, on the waist belt of a workman using the system.

While various descriptions of the present invention are described above, it should be understood that the various features can be used singly or in any combination thereof. Therefore, this invention is not to be limited to only the specifically preferred embodiments depicted herein.

Further, it should be understood that variations and modifications within the spirit and scope of the invention may occur to those skilled in the art to which the invention pertains. For example, the bladder-based delivery systems of the present invention may be used in supercritical fluid extraction and supercritical fluid chromatography, in order to minimize the presence of impurities in the delivered supercritical fluid. Furthemore, the bladder-based delivery systems of the present invention may be used in industrial painting applications, such as automotive painting. In addition, each of the delivery systems may be configured to be portable, for example, as a back-pack unit. Also, other embodiments may include more than two pressure vessels. For example, a coating delivery system may include two pressure vessels for storing and selectively delivering different deliverable substances, while a third pressure vessel may be included for storing pressure conveying fluid. Alternatively, a coating delivery system may include several pressure vessels of a standardized size which contain the same deliverable substance, thereby in the aggregate providing greater volume of available deliverable substance when a coating is being applied. Accordingly, all expedient modifications readily attainable by one versed in the art from the disclosure set forth herein that are within the scope and spirit of the present invention are to be included as further embodiments of the present invention. The scope of the present invention is accordingly defined as set forth in the appended claims.

1. A coating delivery system comprising:
a first pressure vessel having an inner surface;
a flexible bladder disposed in the first pressure vessel and having an open condition and a closed condition;
an internal region disposed between the inner surface and the bladder;
a deliverable substance comprising a coating component interspersed with at least one of liquefied carbon dioxide and supercritical carbon dioxide;
a pressure-conveying fluid provided (1) at a pressure greater than the vapor pressure of carbon dioxide if the deliverable substance comprises liquefied carbon dioxide, or (2) at a pressure greater than the critical pressure of carbon dioxide if the deliverable substance is supercritical carbon dioxide,
wherein the deliverable substance is disposed in one of the flexible bladder and the internal region, and the pressure-conveying fluid is received in the other to exert pressure on the deliverable substance and thereby permit transport thereof when the flexible bladder is in the open condition.

2. The coating delivery system of claim 1, further comprising a second pressure vessel, wherein the pressure-conveying fluid is stored in the second pressure vessel in communication with one of the internal region of the first pressure vessel and the flexible bladder.

3. The coating delivery system of claim 2, further comprising a regulator for regulating the transport of pressure-conveying fluid from the second pressure vessel to the first pressure vessel.

4. The coating delivery system of claim 1, wherein the pressure-conveying fluid comprises a gas.

5. The coating delivery system of claim 1, wherein the pressure-conveying fluid comprises a liquid.

6. The coating delivery system of claim 1, wherein the coating component comprises a fluorinated resin.

7. The coating delivery system of claim 1, wherein the flexible bladder comprises an elastomeric material.

8. The coating delivery system of claim 1, wherein the first pressure vessel is formed of carbon fiber.

9. A method of applying a coating to a substrate comprising:
separating a deliverable substance from a pressurizing fluid with a flexible membrane disposed in a first pressure vessel, the deliverable substance comprising a coating component interspersed with at least one of liquefied carbon dioxide and supercritical carbon dioxide;
allowing the pressurizing fluid to apply pressure to the deliverable substance (1) at a pressure at least the vapor pressure of carbon dioxide if the deliverable substance comprises liquefied carbon dioxide, or (2) at a pressure at least the critical pressure of carbon dioxide if the deliverable substance comprises supercritical carbon dioxide;
delivering the deliverable substance to the substrate.

10. The method of claim 9, wherein the pressurizing fluid is provided in a second pressure vessel that communicates with the first pressure vessel.

11. The method of claim 9, wherein the deliverable substance is provided in a bladder in the first pressure vessel.

12. The method of claim 9, wherein the pressurizing fluid is provided in a bladder in the first pressure vessel.

13. The method of claim 9, further comprising heating the deliverable substance prior to spray discharge.

14. The method of claim 9, further comprising pumping the deliverable substance.

15. The method of claim 9, further comprising agitating the deliverable substance.

16. The method of claim 9, further comprising recirculating a portion of the deliverable substance.
